(19) United States
(12) Patent Application Publication
(10) Pub. No.: US 2024/0431209 A1
(43) Pub. Date: Dec. 26, 2024

(54) TACTILE-FEEDBACK BASE BOARD AND TACTILE-FEEDBACK DEVICE

(71) Applicants: BEIJING BOE TECHNOLOGY DEVELOPMENT CO., LTD., Beijing (CN); BOE Technology Group Co., Ltd., Beijing (CN)

(72) Inventors: Hui Hua, Beijing (CN); Yuju Chen, Beijing (CN); Yingzi Wang, Beijing (CN)

(73) Assignees: BEIJING BOE TECHNOLOGY DEVELOPMENT CO., LTD., Beijing (CN); BOE Technology Group Co., Ltd., Beijing (CN)

(21) Appl. No.: 18/687,413

(22) PCT Filed: Oct. 21, 2022
(86) PCT No.: PCT/CN2022/126595

§ 371 Date: Feb. 28, 2024

(51) Int. Cl. H10N 30/20; G06F 3/01; H10N 30/85; H10N 30/87

(52) U.S. Cl. CPC H10N 30/206; G06F 3/016; H10N 30/852; H10N 30/872

(57) ABSTRACT

A tactile-feedback base board and a tactile-feedback device are provided by the embodiments of the present disclosure. The tactile-feedback base board includes a substrate and a piezoelectric element disposed at one side of the substrate, the piezoelectric element includes a first electrode, a piezoelectric material layer and a second electrode arranged in layer configuration, the first electrode is close to the substrate, the first electrode and the second electrode are for forming an alternating electric field, and the piezoelectric material layer is for, under an effect of the alternating electric field, vibrating, and driving the substrate to resonate; and an insulating and planarizing layer is disposed between the first electrode and the piezoelectric material layer and/or between the second electrode and the piezoelectric material layer.

### TECHNICAL FIELD

The present disclosure relates to the technical field of tactile feedback and, more particularly, to a tactile-feedback base board and a tactile-feedback device.

### BACKGROUND

With the development of the technology of displaying, touch screens are more and more widely applied, and have gradually become one of the most convenient human-machine interaction devices. In recent years, in order to further improve the usage experience of human-machine interaction, the technology of tactile feedback emerges as the times require, and has received more and more attention and research.

### SUMMARY

A tactile-feedback base board and a tactile-feedback device are provided by the embodiments of the present disclosure. The specific solutions are as follows:

A tactile-feedback base board is provided by the embodiments of the present application, wherein the tactile-feedback base board includes a substrate and a piezoelectric element disposed at one side of the substrate, the piezoelectric element includes a first electrode, a piezoelectric material layer and a second electrode arranged in layer configuration, the first electrode is disposed closely to the substrate, the first electrode and the second electrode are for forming an alternating electric field, and the piezoelectric material layer is for, under an effect of the alternating electric field, vibrating, and driving the substrate to resonate;

wherein an insulating and planarizing layer is disposed between the first electrode and the piezoelectric material layer and/or between the second electrode and the piezoelectric material layer, and a dielectric constant of the insulating and planarizing layer is less than a dielectric constant of the piezoelectric material layer.

In a possible embodiment, in the tactile-feedback base board stated above according to the embodiments of the present application, a material of the insulating and planarizing layer includes at least one of HfO₂, Al₂O₃, AlN or PbZrO₃.

In a possible embodiment, in the tactile-feedback base board stated above according to the embodiments of the present application, the insulating and planarizing layer is disposed between the first electrode and the piezoelectric material layer or between the second electrode and the piezoelectric material layer, and a thickness of the insulating and planarizing layer satisfies a following relation:

$$10 nm \leq {l}_{2} \leq [ ( \frac{{ε}_{2} - {ε}_{1}}{2 {ε}_{2} - {ε}_{1}} ) {l}_{1} - {l}_{1} ] nm ;$$

wherein l₂ is the thickness of the insulating and planarizing layer, l₁ is a thickness of the piezoelectric material layer, ε₁ is the dielectric constant of the piezoelectric material layer, and ε₂ is the dielectric constant of the insulating and planarizing layer.

In a possible embodiment, in the tactile-feedback base board stated above according to the embodiments of the present application, a first insulating and planarizing layer is disposed between the first electrode and the piezoelectric material layer, a second insulating and planarizing layer is disposed between the second electrode and the piezoelectric material layer, and a thickness of the first insulating and planarizing layer and a thickness of the second insulating and planarizing layer satisfy a following relation:

$$10 nm \leq {l}_{0} \leq [ ( \frac{{ε}_{2} - {ε}_{1}}{2 {ε}_{2} - {ε}_{1}} ) {l}_{1} - {l}_{1} ] nm ;$$

wherein l₀ is a sum of the thickness of the first insulating and planarizing layer and the thickness of the second insulating and planarizing layer, l₁ is a thickness of the piezoelectric material layer, ε₁ is the dielectric constant of the piezoelectric material layer, and ε₂ is a dielectric constant of the first insulating and planarizing layer.

In a possible embodiment, in the tactile-feedback base board stated above according to the embodiments of the present application, a quantity of the piezoelectric element is more than one, and a plurality of piezoelectric elements are arranged in an array at one side of the substrate;

the first electrodes of all of the piezoelectric elements are planar electrodes of an integral structure, the second electrodes of the piezoelectric elements located in a same column are electrically connected to each other by electrically conductive connecting parts, the second electrodes of the piezoelectric elements located in different columns are insulated from each other, and the piezoelectric material layers of the piezoelectric elements located in the same column are connected to each other by piezoelectric connecting parts; and

the insulating and planarizing layers and the piezoelectric material layers have a same shape and equal sizes.

In a possible embodiment, in the tactile-feedback base board stated above according to the embodiments of the present application, edges of the second electrodes may be retracted relative to edges of the piezoelectric material layers.

In a possible embodiment, in the tactile-feedback base board stated above according to the embodiments of the present application, a retraction amount of the edges of the second electrodes relative to the edges of the piezoelectric material layers is greater than or equal to 50 micrometers, and less than or equal to 100 micrometers.

In a possible embodiment, in the tactile-feedback base board stated above according to the embodiments of the present application, sizes of the piezoelectric elements located in the same column are equal, and the piezoelectric elements located in a same row are arranged alternately based on a first size and a second size, wherein the first size is greater than the second size.

In a possible embodiment, in the tactile-feedback base board stated above according to the embodiments of the present application, the tactile-feedback base board further includes:
a bonding electrode disposed in a same layer as the first electrode, wherein the bonding electrode is disposed closely to an edge of the substrate, the bonding electrode is for connecting a driving-voltage inputting terminal, and a voltage signal inputted by the driving-voltage inputting terminal is an alternating voltage signal;
an insulating layer disposed at one side of the second electrode away from the substrate; and
a trace layer disposed at one side of the insulating layer away from the substrate, wherein the trace layer includes a trace, one end of the trace is connected to the second electrode by a first via hole disposed in the insulating layer, and the other end of the trace is connected to the bonding electrode by a second via hole disposed in the insulating layer.

In a possible embodiment, in the tactile-feedback base board stated above according to the embodiments of the present application, the tactile-feedback base board further includes a lead-wire electrode disposed in the same layer as the first electrode, the lead-wire electrode is connected to the first electrode, the lead-wire electrode is for connecting a ground-voltage inputting terminal, and a voltage signal inputted by the ground-voltage inputting terminal is a grounded voltage signal.

In a possible embodiment, in the tactile-feedback base board stated above according to the embodiments of the present application, a material of the insulating layer is SiO₂ or a photoresist. In a possible embodiment, in the tactile-feedback base board stated above according to the embodiments of the present application, a material of the first electrode and a material of the second electrode are a transparent electrically conductive material, and a material of the trace layer is Ti/Ni/Au or Ti/Al/Ti.

In a possible embodiment, in the tactile-feedback base board stated above according to the embodiments of the present application, a thickness of the piezoelectric material layer is 500 nm-2000 nm.

In a possible embodiment, in the tactile-feedback base board stated above according to the embodiments of the present application, the piezoelectric material layer includes at least one of lead zirconate titanate, aluminium nitride, zinc oxide, barium titanate, lead titanate, potassium niobate, lithium niobate, lithium tantalate and gallium lanthanum silicate.

Correspondingly, a tactile-feedback device is further provided by an embodiment of the present disclosure, wherein the tactile-feedback device includes the tactile-feedback base board according to the embodiments of the present disclosure.

### BRIEF DESCRIPTION OF THE DRAWINGS

FIG. 1 is a schematic structural diagram of a piezoelectric element provided in the related art;

FIG. 2 is a schematic structural diagram of a tactile-feedback base board according to an embodiment of the present disclosure;

FIG. 3 is a schematic structural diagram of another tactile-feedback base board according to an embodiment of the present disclosure;

FIG. 4 is a schematic structural diagram of another tactile-feedback base board according to an embodiment of the present disclosure;

FIG. 5 is a photograph of atomic force microscope of the piezoelectric material layer according to an embodiment of the present disclosure;

FIG. 6 is the heights of the needle-like protrusions of the surface of the piezoelectric material layer corresponding to FIG. 5;

FIG. 7 is a schematic structural diagram when the insulating and planarizing layer is disposed at the surface of the piezoelectric material layer having the needle-like protrusions;

FIG. 8 is a schematic diagram of the relation between the thickness l₂ of the insulating and planarizing layer (the materials are individually HfO₂, Al₂O₃, AlN and PbZrO₃) and E1/E;

FIG. 9 is a schematic view of a plane of a tactile-feedback base board according to an embodiment of the present disclosure;

FIG. 10 is a schematic view of a cross-section in the direction of CC′ in FIG. 9; and

FIG. 11 is a schematic structural diagram of another tactile-feedback base board according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. Furthermore, subject to the avoiding of any conflict, the embodiments and the features of the embodiments of the present disclosure may be combined. All of the other embodiments that a person skilled in the art obtains on the basis of the described embodiments of the present disclosure without paying creative work fall within the protection scope of the present disclosure.

Unless defined otherwise, the technical terminologies or scientific terminologies used in the present disclosure should have the meanings generally understood by a person skilled in the art of the present disclosure. The words such as “include” or “include” used herein mean that the element or article preceding the word encompasses the elements or articles and the equivalents thereof that are listed subsequent to the word, but do not exclude other elements or articles. The words such as “connect” or “couple” are not limited to physical or mechanical connections, but may include electric connections, regardless of direct connections or indirect connections. The words such as “inner”, “outer”, “upper” and “lower” are merely intended to indicate relative positions, and if the absolute position of the described item has changed, the relative positions might also be correspondingly changed.

It should be noted that the sizes and the shapes of the patterns in the drawings do not reflect the true proportions, and merely illustratively describe the contents of the present disclosure. Furthermore, the same or similar reference numbers throughout the drawings indicate the same or similar elements or elements having the same or similar functions.

Thin-film piezoelectric materials have the characteristics of a high dielectric constant and transparency, and are very suitable for a vibrator structure integrated with the screen. Lead-zirconate-titanate piezoelectric ceramic (PZT), because of the excellent piezoelectric performance, is applied extensively currently.

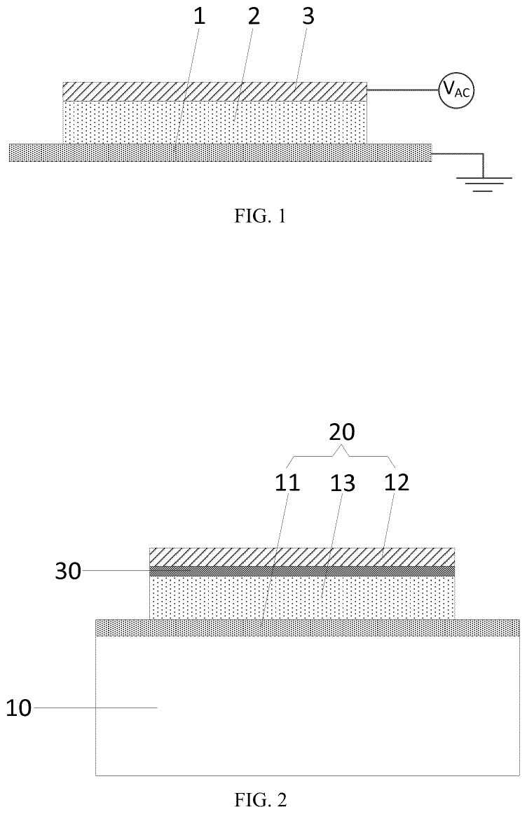

In the related art, as shown in FIG. 1, a piezoelectric elements includes a first electrode 1 (for example, ITO), a piezoelectric material layer 2 (for example, PZT) disposed on the first electrode 1, and a second electrode 3 (for example, ITO) disposed on the piezoelectric material layer 2. In the operating process of the piezoelectric element, by using the inverse piezoelectric effect, the first electrode 1 is connected to ground, and by that the second electrode 3 is loaded with a high-frequency alternating voltage signal (VAC), the application of the high-frequency alternating voltage signal to the piezoelectric material layer 2 is realized, thereby a high-frequency vibration is generated. The inventor of the present disclosure has found by study that the reason for the breakdown damage of the piezoelectric element is mainly that the second electrode 3 (ITO) and the piezoelectric material layer 2 (PZT) are seriously damaged, and the particular reasons for the serious damage of the second electrode 3 and the piezoelectric material layer 2 are as follows:
(1) Because the Pb ions in the PZT film layer very easily diffuse into the ITO film layer, the resistance of the ITO increases. When an electric current passes through a large resistor, the electric current works to consume the electric energy, to generate more heat, which results in breakdown of the piezoelectric element.
(2) The PZT film layer is usually fabricated by using the process of dry film-coating (sputtering) or wet film-coating (sol-gel). However, the PZT film layers fabricated and obtained by using the two methods have a large quantity of defects, such as internal grain boundaries and voids, and the surface of the PZT film layers has needle-like uneven protrusions. As a result, they are broken down directly in the electric field and become a conductor, the current value sharply increases, and the heat sharply increases, which causes that the phenomenon of breakdown damage of the piezoelectric element is easy to occur under the operation voltage.

In view of the above, in order to prevent the problem that the piezoelectric element is broken down, which causes damage of the piezoelectric element, an embodiment of the present disclosure provides a tactile-feedback base board. As shown in FIG. 2 to FIG. 4, the tactile-feedback base board includes a substrate 10 and a piezoelectric element 20 disposed at one side of the substrate 10, the piezoelectric element 20 includes a first electrode 11, a piezoelectric material layer 13 and a second electrode 12 arranged in layer configuration, the first electrode 11 is disposed closely to the substrate 10, the first electrode 11 and the second electrode 12 are for forming an alternating electric field, and the piezoelectric material layer 13 is for, under an effect of the alternating electric field, vibrating, and driving the substrate 11 to resonate.

An insulating and planarizing layer 30 is disposed between the first electrode 11 and the piezoelectric material layer 13 and/or between the second electrode 12 and the piezoelectric material layer 13, and the dielectric constant of the insulating and planarizing layer 30 is less than the dielectric constant of the piezoelectric material layer 13.

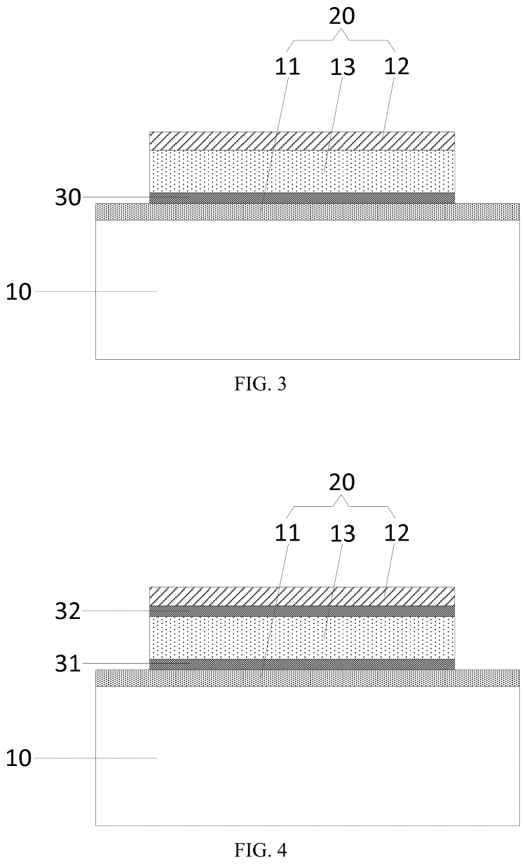

In the tactile-feedback base board stated above according to the embodiments of the present disclosure, as shown in FIG. 2, by disposing between the second electrode 12 and the piezoelectric material layer 13 the insulating and planarizing layer 30 whose dielectric constant is less than the dielectric constant of the piezoelectric material layer 13, the insulating and planarizing layer 30 can prevent the Pb in the piezoelectric material layer 13 (for example, PZT) from diffusing into the second electrode 12 (for example, ITO), and the insulating and planarizing layer 30 can further planarize the void defects existing in the piezoelectric material layer 13, which can reach the effect of stabilizing the electric field and reducing the leakage current, thereby the problem that the piezoelectric material layer 13 is locally broken down in the alternating electric field is solved, to further improve the stability and the reliability of the operation of the piezoelectric element 20. As shown in FIG. 3, by disposing between the first electrode 11 and the piezoelectric material layer 13 the insulating and planarizing layer 30 whose dielectric constant is less than the dielectric constant of the piezoelectric material layer 13, the insulating and planarizing layer 30 can prevent the Pb in the piezoelectric material layer 13 (for example, PZT) in the deposition and the high-temperature crystallization heat treatment process from diffusing into the first electrode 11 (for example, ITO), thereby the electric conductivity of the first electrode 11 is increased. As shown in FIG. 4, by disposing the insulating and planarizing layers (31, 32) whose dielectric constant is less than the dielectric constant of the piezoelectric material layer 13 both between the second electrode 12 and the piezoelectric material layer 13 and between the first electrode 11 and the piezoelectric material layer 13, in an aspect, the Pb in the piezoelectric material layer 13 (for example, PZT) can be prevented from diffusing into the second electrode 12 and the first electrode 11, and, in another aspect, the void defects existing in the piezoelectric material layer 13 can be planarized.

In particular implementations, the substrate 10 may be a base board fabricated by using glass, may also be a base board fabricated by using silicon or silicon dioxide (SiO₂), may also be a base board fabricated by using sapphire, and may also be a base board fabricated by using a metal wafer, which is not limited herein. A person skilled in the art may configure the substrate 10 according to practical applications and demands.

In particular implementations, in the tactile-feedback base board stated above according to the embodiments of the present disclosure, the material of the insulating and planarizing layer may include at least one of HfO₂, Al₂O₃, AlN or PbZrO₃. Specifically, when the material of the insulating and planarizing layer is HfO₂, Al₂O₃ or AlN, the technique of atom-layer deposition (ALD) may be employed. ALD is a thin-film preparing technique in which atom-degree film layers are grown layer by layer. The traditional techniques of vapor deposition, sputtering and chemical vapor deposition may generate voids and surface layer defects. However, the technique of atom-layer deposition can effectively ensure the evenness of the thickness, and has a good reproducibility, a low stress and an accurate stoichiometry, and the amorphous structure with a low defect density may be used as an effective electron blocking layer. When the material of the insulating and planarizing layer is PbZrO₃, it may be fabricated by using the method of sol-gel or magnetron sputtering.

It should be noted that, as compared with the insulating materials of HfO₂ and PbZrO₃, if the insulating and planarizing layer employs the AlN material, it cannot only serve as the planarizing layer and the insulating layer, but also, because AlN is also a piezoelectric material, can similarly contribute to a part of the piezoelectricity function, which facilitates to increase the overall vibration displacement of the piezoelectric element.

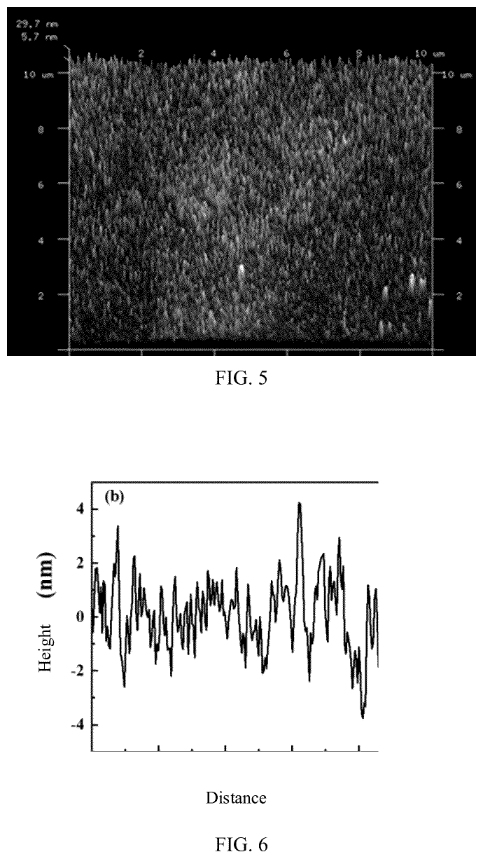

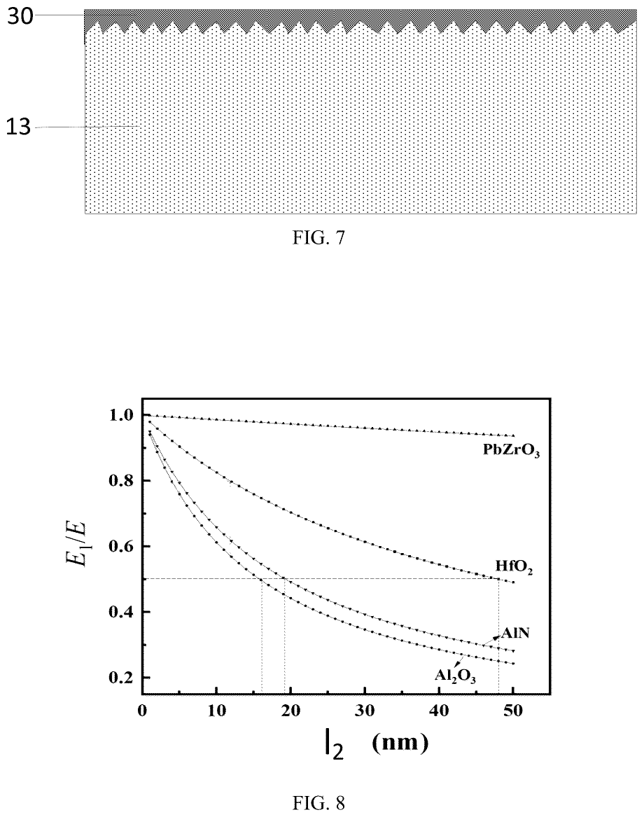

As shown in FIG. 5, FIG. 5 is a photograph of atomic force microscope (AFM) of a piezoelectric material layer (PZT) fabricated by using the method of sputtering or sol-gel. It can be seen that the surface of the original PZT film layer has a large quantity of needle-like protrusions. As shown in FIG. 6, FIG. 6 shows the heights of the needle-like protrusions of the surface of the PZT film layer, wherein the maximum height difference of the needle-like protrusions ΔH>8 nm. Therefore, in order to sufficiently cover the PZT film layer, as shown in FIG. 7, FIG. 7 is a schematic diagram when the surface of the PZT film layer is covered by the insulating and planarizing layer 30. The thickness of the insulating and planarizing layer 30 should be greater than 10 nm.

However, the thickness of the insulating and planarizing layer 30 has an upper limit. That is because, regarding the structure of the piezoelectric elements of Glass/ITO/PZT/ITO, the thickness of the PZT film layer is usually set to be 2 μm, and when the two ends of the electrode are applied with equal voltages, it is required to sufficiently configure the material selection and the thickness of the insulating and planarizing layer, thereby that the effective electric-field intensity at the two ends of the PZT film layer is not lost too much is ensured.

$$E 1 = \frac{1}{{α}_{1} + ( 1 - {α}_{1} ) {ε}_{1} / {ε}_{2}} E \qquad formula ( 1 )$$

$$E = E 1 + E 2 \qquad formula ( 2 )$$

$${α}_{1} = {l}_{1} / ( {l}_{1} + {l}_{2} ) \qquad formula ( 3 )$$

wherein E is the electric field formed in the piezoelectric element when the first electrode and the second electrode are applied with voltages, E1 and E2 are the electric fields in the piezoelectric material layer and the insulating and planarizing layer respectively, ε₁ and ε₂ are the dielectric constants of the piezoelectric material layer and the insulating and planarizing layer respectively, and l₁ and l₂ are the thicknesses of the piezoelectric material layer and the insulating and planarizing layer respectively. Because the insulating and planarizing layer may divide the voltage, the electric field E1 in the piezoelectric material layer is less than the external electric field E.

From the above formulas, it can be seen that, if the dielectric constant ε₂ of the insulating and planarizing layer is lower, and the thickness l₂ is higher, the dissipation of the effective electric field in the piezoelectric material layer is more serious. Generally, it is desirable that the loss of the electric field at the two ends of the piezoelectric material layer does not exceed 50%, and therefore the insulating and planarizing layer is required to be selected from different thicknesses according to the different materials, to block the Pb in PZT from diffusing toward ITO and planarize the surface of the PZT film layer, to prevent the piezoelectric element from being broken down and failing.

As shown in Table 1, table 1 shows the dielectric constants of the materials of PZT, HfO₂, Al₂O₃, AlN and PbZrO₃.

TABLE 1

| film layer | PZT | HfO₂ | Al₂O₃ | PbZrO₃ | AlN |
|---|---|---|---|---|---|
| dielectric constant | 1000 | 23 | 7.8 | 266 | 9.5 |

For example, when the material of the insulating and planarizing layer is HfO₂, and the thickness of the piezoelectric material layer (PZT) is set to be 2000 nm, if it is set that the effective electric field at the two ends of the PZT film layer E1 is ≥50% E (formula (4)), by substituting ε₁=1000 and ε₂=23 into the formula (1), the relation between E1/E and the thickness l₂ of HfO₂ can be obtained, i.e.:

$$E 1 / E = \frac{1}{2000 / ( 2000 + {l}_{2} ) + \{ 1 - [ 2000 / ( 2000 + {l}_{2} ) ] \} * ( 1000 / 23 )} .$$

Likewise, when the material of the insulating and planarizing layer is

$${Al}_{2} {O}_{3} , E 1 / E = \frac{1}{2000 / ( 2000 + {l}_{2} ) + \{ 1 - [ 2000 / ( 2000 + {l}_{2} ) ] \} * ( 1000 / 7.8 )} ;$$

When the material of the insulating and planarizing layer is

$${PbZrO}_{3} , E 1 / E = \frac{1}{2000 / ( 2000 + {l}_{2} ) + \{ 1 - [ 2000 / ( 2000 + {l}_{2} ) ] \} * ( 1000 / 266 )} ;$$

and

When the material of the insulating and planarizing layer is

$$AlN , E 1 / E = \frac{1}{2000 / ( 2000 + {l}_{2} ) + \{ 1 - [ 2000 / ( 2000 + {l}_{2} ) ] \} * ( 1000 / 905 )} .$$

As shown in FIG. 8, FIG. 8 is a schematic diagram of the relation between the thickness l₂ of the insulating and planarizing layer (the materials are individually HfO₂, Al₂O₃, AlN and PbZrO₃) and E1/E. It can be seen that, if it is intended that E1/E is ≥50%, when the material of the insulating and planarizing layer is Al₂O₃, l₂ is required to be less than or equal to 16 nm, or, in other words, 10 nm<l₂≤16 nm. When the material of the insulating and planarizing layer is AlN, l₂ is required to be less than or equal to 19 nm, or, in other words, 10 nm<l₂≤19 nm. When the material of the insulating and planarizing layer is HfO₂, l₂ is required to be less than or equal to 48 nm, or, in other words, 10 nm<l₂≤48 nm. When the material of the insulating and planarizing layer is PbZrO₃, l₂ should always satisfy E1/E≥50% in the range less than or equal to 50 nm, and, in order not to increase the thickness of the piezoelectric element, it may be selected that 10 nm<l₂≤15 nm, which, certainly, is not limited thereto.

On the basis of the above analysis, as shown in FIG. 2 and FIG. 3, the thickness of the insulating and planarizing layer 30, as deduced by using the formulas (1)-(4), may satisfy the following relation:

$$10 nm \leq {l}_{2} \leq [ ( \frac{{ε}_{2} - {ε}_{1}}{2 {ε}_{2} - {ε}_{1}} ) {l}_{1} - {l}_{1} ] nm .$$

As shown in FIG. 4, because a first insulating and planarizing layer 31 is disposed between the first electrode 11 and the piezoelectric material layer 13, and a second insulating and planarizing layer 32 is disposed between the second electrode 12 and the piezoelectric material layer 13, the sum of the thickness of the first insulating and planarizing layer 31 and the thickness of the second insulating and planarizing layer 32, as deduced by using the formulas (1)-(4), may satisfy the following relation:

$$10 nm \leq {l}_{0} \leq [ ( \frac{{ε}_{2} - {ε}_{1}}{2 {ε}_{2} - {ε}_{1}} ) {l}_{1} - {l}_{1} ] nm ;$$

wherein l₀ is the sum of the thickness of the first insulating and planarizing layer 31 and the thickness of the second insulating and planarizing layer 32.

In conclusion, when the thickness of the insulating and planarizing layer 30 in FIG. 2 and FIG. 3 satisfies the relation of

$$10 nm \leq {l}_{2} \leq [ ( \frac{{ε}_{2} - {ε}_{1}}{2 {ε}_{2} - {ε}_{1}} ) {l}_{1} - {l}_{1} ] nm ,$$

the effective electric field at the two ends of the piezoelectric material layer 20 E1 is ≥50% E. When the sum of the thicknesses of the insulating and planarizing layers 31, 32 in FIG. 4 satisfies the relation of

$$10 nm \leq {l}_{0} \leq [ ( \frac{{ε}_{2} - {ε}_{1}}{2 {ε}_{2} - {ε}_{1}} ) {l}_{1} - {l}_{1} ] nm ,$$

the effective electric field at the two ends of the piezoelectric material layer 20 E1 is ≥50% E.

In particular implementations, in the tactile-feedback base board stated above according to the embodiments of the present disclosure, as shown in FIG. 9, a quantity of the piezoelectric element 20 may be more than one, and the plurality of piezoelectric elements 20 are arranged in an array at one side of the substrate 10.

The first electrodes 11 of all of the piezoelectric elements 20 may be planar electrodes of an integral structure, the second electrodes 12 of the piezoelectric elements 20 located in the same column are electrically connected to each other by electrically conductive connecting parts 14, the second electrodes 12 of the piezoelectric elements 20 located in different columns are insulated from each other, and the piezoelectric material layers 13 of the piezoelectric elements 20 located in the same column are connected to each other by piezoelectric connecting parts (not shown). Accordingly, the piezoelectric elements 20 in the same column can be driven integrally, thereby column driving is realized.

The insulating and planarizing layers 30 and the piezoelectric material layers 13 have the same shape and equal sizes. Accordingly, the insulating and planarizing layers 30 can completely planarize the piezoelectric material layers 13 and completely block the Pb in the piezoelectric material layers 13 from diffusing toward the first electrodes 11 or the second electrodes 12.

Specifically, the first electrodes 11 are disposed as a whole face. The piezoelectric material layers 13 and the insulating and planarizing layers 30 are patterned, and the edges are etched, to facilitate the first electrodes 11 to be exposed to be applied with the electric signals. The second electrodes 12 are deposited on the insulating and planarizing layers 30 and patterned, and the patterns of the second electrodes 12 maintain consistent with those of the piezoelectric material layers 13 and the insulating and planarizing layers 30, to realize the plurality of piezoelectric elements 20 that are distributed in an array on the substrate 10.

It should be noted that FIG. 9 of the embodiments of the present disclosure is illustrated by taking the case as an example in which the first electrodes 11 are disposed as a whole face, and certainly the shapes of the first electrodes 11 may also be the same as the shapes of the second electrodes 12. However, the areas of the orthographic projections of the first electrodes 11 on the substrate 10 should be greater than the areas of the orthographic projections of the second electrodes 12 on the substrate 10, to facilitate the first electrodes 11 to be exposed to be applied with the electric signals.

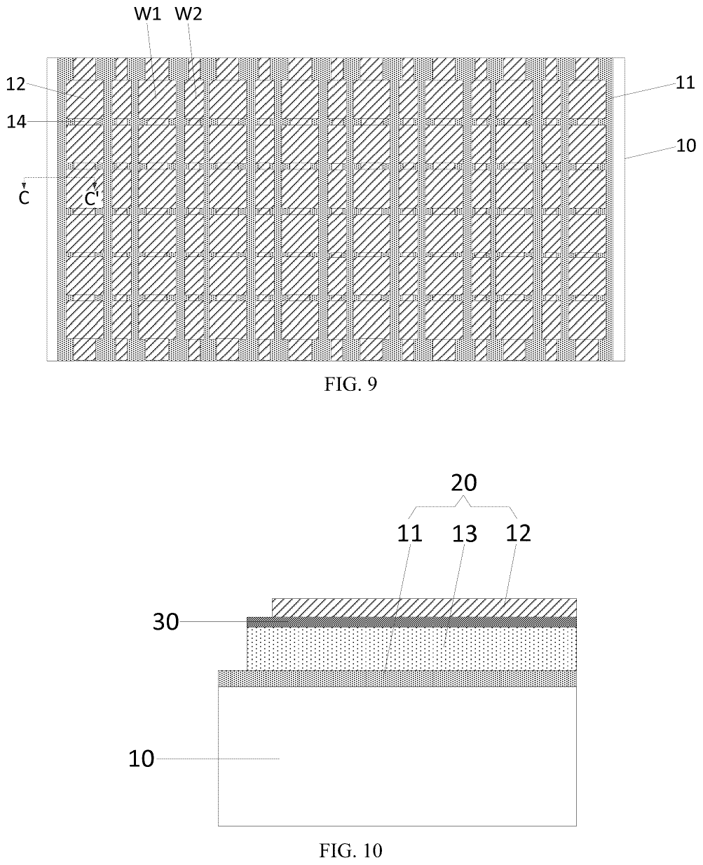

In particular implementations, in order to reduce the risk in short circuiting, in the tactile-feedback base board stated above according to the embodiments of the present disclosure, as shown in FIG. 10, wherein FIG. 10 is a schematic view of a cross-section in the direction of CC′ in FIG. 9, the edges of the second electrodes 12 may be retracted relative to the edges of the piezoelectric material layers 13. In particular implementations, the retraction amount of the edges of the second electrodes 12 relative to the edges of the piezoelectric material layers 13 is greater than or equal to 50 micrometers, and less than or equal to 100 micrometers. For example, the retraction amount may be 100 micrometers. Furthermore, as compared with the whole piezoelectric material layer 13 and insulating and planarizing layer 30 described above, the stress of the whole piezoelectric elements 20 can be reduced, warping of the substrate 10 is reduced, and the reliability of the piezoelectric elements in fabrication and operation is improved.

In order to further reduce the risk in short circuiting, as shown in FIG. 10, the edges of the piezoelectric material layers 13 may be retracted relative to the edges of the first electrodes 11.

In particular implementations, in the tactile-feedback base board stated above according to the embodiments of the present disclosure, as shown in FIG. 9, the sizes of the piezoelectric elements 20 located in the same column are equal, and the piezoelectric elements 20 located in the same row are arranged alternately based on a first size W1 and a second size W2, wherein the first size W1 is greater than the second size W2. The purpose of configuring the piezoelectric elements 20 in that way is that, when it is required to perform tactile feedback, merely the piezoelectric elements 20 of the first size may be loaded the alternating voltage signal, but the piezoelectric elements 20 of the second size are not loaded the alternating voltage signal. Accordingly, the piezoelectric elements 20 of the first size vibrate to drive the substrate to vibrate to realize the tactile feedback, and the piezoelectric elements 20 of the second size can use the direct piezoelectric effect of the piezoelectric material layers to realize pressure detection, which can realize simultaneous performance of the tactile feedback and the pressure detection. Because the piezoelectric elements 20 of the second size are merely used for the pressure detection, the piezoelectric elements 20 of the second size may be configured to have a lower size, and the piezoelectric elements 20 of the first size may be configured to have a higher size, the effect of the tactile feedback can be improved.

Specifically, the piezoelectric elements 20 of the first size are disposed at the positions of the wave peaks of the vibration of the substrate, and the piezoelectric elements 20 of the second size are disposed at the positions of the wave troughs of the vibration of the substrate.

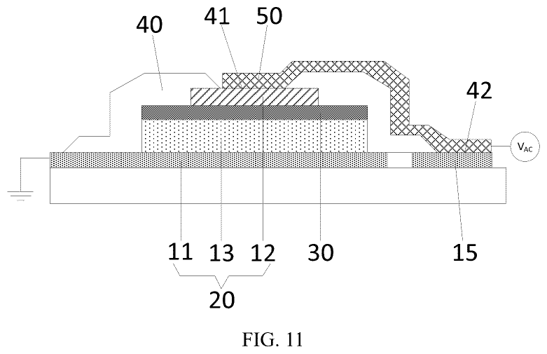

In particular implementations, in the tactile-feedback base board stated above according to the embodiments of the present disclosure, as shown in FIG. 11, the tactile-feedback base board further includes:

a bonding electrode 15 disposed in a same layer as the first electrode 11, wherein the bonding electrode 15 is disposed closely to the edge of the substrate 10, the bonding electrode 15 is for connecting a driving-voltage inputting terminal, and the voltage signal inputted by the driving-voltage inputting terminal is an alternating voltage signal;

an insulating layer 40 disposed at one side of the second electrode 12 away from the substrate 10; and

a trace layer 50 disposed at one side of the insulating layer 40 away from the substrate 10, wherein the trace layer 50 includes a trace, one end of the trace is connected to the second electrode 12 by a first via hole 41 disposed in the insulating layer 40, and the other end of the trace is connected to the bonding electrode 15 by a second via hole 42 disposed in the insulating layer 40.

In particular implementations, in the tactile-feedback base board stated above according to the embodiments of the present disclosure, as shown in FIG. 11, the tactile-feedback base board further includes a lead-wire electrode (not shown) disposed in the same layer as the first electrode 11, the lead-wire electrode is connected to the first electrode 11, the lead-wire electrode is for connecting a ground-voltage inputting terminal, and the voltage signal inputted by the ground-voltage inputting terminal is a grounded voltage signal.

In an embodiment of the present disclosure, the first electrode 11, the bonding electrode 15 and the lead-wire electrode may have the same material and be formed by using the same patterning process.

The insulating layer 40 may employ SiO₂, a negative photoresist or a positive photoresist. After the material film layer of the insulating layer has been spread-coated or deposited on the whole face, the material film layer of the insulating layer is patterned. The purpose of disposing the insulating layer 40 is to cover a part of the first electrode 11 to prevent it from short-circuiting with the other components via the trace layer 50, and, at the same time, forming the first via hole 41 at the position of the second electrode 12, and forming the second via hole 42 at the position of the bonding electrode 15, so that one end of the trace in the trace layer 50 is connected to the second electrode 12 by the first via hole 41, and the other end of the trace is connected to the bonding electrode 15 by the second via hole 42. Moreover, a lead-wire-electrode via hole may be formed at the position of the lead-wire electrode, so that an externally connected lead wire is connected to the lead-wire electrode by silver adhesive and so on.

It should be noted that FIG. 11 is illustrated by taking the case as an example in which the insulating layer 40 and the trace layer 50 are disposed on the basis of FIG. 2, and certainly the insulating layer 40 and the trace layer 50 may also be disposed on the basis of FIG. 3 or 4.

In particular implementations, in the tactile-feedback base board stated above according to the embodiments of the present disclosure, besides the film layers mentioned above, other film layers may be disposed according to practical applications.

Optionally, the length-width ratio of the entire substrate may be 1.8-2.0, and the thickness of the substrate may be 0.5 mm-1 mm.

Optionally, as shown in FIG. 9, the lengths and the widths of the second electrodes corresponding to the piezoelectric elements 20 of the first size W1 may be equal, for example, 5 mm-10 mm. The widths of the piezoelectric elements 20 of the second size W2 may be equal to the widths of the second electrodes of the piezoelectric elements 20 of the first size. The lengths of the piezoelectric elements 20 of the second size W2 may be a half of the widths.

In particular implementations, in the tactile-feedback base board stated above according to the embodiments of the present disclosure, the material of the first electrode 11 and the material of the second electrode 12 may be a transparent electrically conductive material. For example, they may be indium tin oxide (ITO), and may also be indium zinc oxide (IZO) and so on. A person skilled in the art may configure the materials of the first electrode 11 and the second electrode 12 according to practical applications and demands, which is not limited herein. The tactile-feedback base board according to the embodiments of the present disclosure may be a glass-based transparent tactile-feedback device, and may be used for displaying integration. Its overall average transmittance is >75%. As compared with the Ti/Pt electrodes in the related art, both of ITO and PZT are metal oxides, and have a better adhesiveness, to prevent the electrodes from generating a phenomenon of stripping and splitting in vibration using process.

In particular implementations, in the tactile-feedback base board stated above according to the embodiments of the present disclosure, the material of the trace layer may be Ti/Ni/Au, or the material of the trace layer may be Ti/Al/Ti.

In particular implementations, in the tactile-feedback base board stated above according to the embodiments of the present disclosure, the thickness of the piezoelectric material layer may be 500 nm-2000 nm. For example, the thickness of the piezoelectric material layer is 500 nm, 1000 nm or 2000 nm. In practical applications, the thickness of the piezoelectric material layer may be set to approach zero to the largest extent, which, while ensuring a good vibration performance of the piezoelectric material layer, takes into consideration the design of low weight and thickness of the tactile-feedback base board.

In particular implementations, the piezoelectric material layer is not limited to the above-described lead zirconate titanate (Pb(Zr,Ti)O₃, PZT), and may also be at least one of aluminium nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃) and gallium lanthanum silicate (La₃Ga₅SiO₁₄). In this way, while taking into consideration the transparency of the tactile-feedback base board, the vibration performance of the tactile-feedback base board is ensured. The material for fabricating the piezoelectric material layer may be selected specifically according to the practical usage demands of a person skilled in the art, which is not limited herein. When the piezoelectric material layer is fabricated by using PZT, because PZT has a high piezoelectric coefficient, the piezoelectric property of the corresponding tactile-feedback base board is ensured, and the corresponding tactile-feedback base board can be applied to tactile-feedback devices. Moreover, PZT has a high light transmittance, and when it is integrated into displaying devices, the quality of displaying of the displaying devices is not affected.

The tactile-feedback base board according to the embodiments of the present disclosure may be applied to the fields such as medical treatment, vehicle electronics and movement tracking systems, and is especially suitable for wearable devices, medical monitoring and treatment in vitro or when implanted into human body, and the electronic skin for artificial intelligence. Specifically, the tactile-feedback base board may be applied to devices that can generate vibration and mechanical properties, such as a brake block, a keyboard, a mobile terminal, a gamepad and a vehicle-mounted device.

On the basis of the same inventive concept, a tactile-feedback device is further provided by an embodiment of the present disclosure, wherein the tactile-feedback device includes the tactile-feedback base board stated above according to the embodiments of the present disclosure. Because the principle of solving the problem by the tactile-feedback device is similar to that of the tactile-feedback base board, the implementation of the tactile-feedback device may refer to the implementation of the tactile-feedback base board described above, and the repeated parts are not discussed further.

In specific implementations, the tactile-feedback device may be integrated with a touch screen, and the touch screen may be used to determine the position of the human-body touch controlling, thereby the corresponding vibration waveform, amplitude and frequency are generated to realize human-machine interaction. As another example, the tactile-feedback device may be further used as a piezoelectric body, and the tactile-feedback base board is used to determine the position of the human-body touch controlling, thereby the corresponding vibration waveform, amplitude and frequency are generated, the human-machine interaction can be realized. Certainly, the tactile-feedback device may also be applied to the fields such as medical treatment, vehicle electronics and movement tracking systems according to practical demands, which is not described in detail herein.

In the tactile-feedback base board and the tactile-feedback device according to the embodiments of the present disclosure, by disposing between the second electrode and the piezoelectric material layer the insulating and planarizing layer whose dielectric constant is less than the dielectric constant of the piezoelectric material layer, the insulating and planarizing layer can prevent the Pb in the piezoelectric material layer (for example, PZT) from diffusing into the second electrode (for example, ITO), and the insulating and planarizing layer can planarize the void defects existing in the piezoelectric material layer, which can reach the effect of stabilizing the electric field and reducing the leakage current, thereby the problem that the piezoelectric material layer is locally broken down in the alternating electric field is solved, to further improve the stability and the reliability of the operation of the piezoelectric element. By disposing between the first electrode and the piezoelectric material layer the insulating and planarizing layer whose dielectric constant is less than the dielectric constant of the piezoelectric material layer, the insulating and planarizing layer can prevent the Pb in the piezoelectric material layer (for example, PZT) in the deposition and the high-temperature crystallization heat treatment from diffusing into the first electrode (for example, ITO), thereby the electric conductivity of the first electrode is increased. By disposing the insulating and planarizing layers whose dielectric constant is less than the dielectric constant of the piezoelectric material layer both between the second electrode and the piezoelectric material layer and between the first electrode and the piezoelectric material layer, in an aspect, the Pb in the piezoelectric material layer (for example, PZT) can be prevented from diffusing into the second electrode and the first electrode, and, in another aspect, the void defects existing in the piezoelectric material layer can be planarized.

Although preferable embodiments of the present disclosure have been described, once a person skilled in the art has known the essential inventive concept, he may make further variations and modifications on those embodiments. Therefore, the appended claims are intended to be interpreted as including the preferable embodiments and all of the variations and modifications that fall within the scope of the present disclosure.

Apparently, a person skilled in the art may make various modifications and variations on the embodiments of the present disclosure without departing from the spirit and the scope of the embodiments of the present disclosure. Accordingly, if those modifications and variations on the embodiments of the present disclosure fall within the scope of the claims of the present disclosure and equivalents thereof, then the present disclosure is also intended to encompass those modifications and variations.

1. A tactile-feedback base board, comprising a substrate and a piezoelectric element disposed at one side of the substrate, wherein the piezoelectric element comprises a first electrode, a piezoelectric material layer and a second electrode arranged in layer configuration, the first electrode is disposed closely to the substrate, the first electrode and the second electrode are for forming an alternating electric field, and the piezoelectric material layer is for, under an effect of the alternating electric field, vibrating, and driving the substrate to resonate;
wherein an insulating and planarizing layer is disposed between the first electrode and the piezoelectric material layer and/or between the second electrode and the piezoelectric material layer, and a dielectric constant of the insulating and planarizing layer is less than a dielectric constant of the piezoelectric material layer.

2. The tactile-feedback base board according to claim 1, wherein a material of the insulating and planarizing layer comprises at least one of HfO₂, Al₂O₃, AlN or PbZrO₃.

3. The tactile-feedback base board according to claim 1, wherein the insulating and planarizing layer is disposed between the first electrode and the piezoelectric material layer or between the second electrode and the piezoelectric material layer, and a thickness of the insulating and planarizing layer satisfies a following relation:
$$10 nm \leq {l}_{2} \leq [ ( \frac{{ε}_{2} - {ε}_{1}}{2 {ε}_{2} - {ε}_{1}} ) {l}_{1} - {l}_{1} ] nm ;$$
wherein l₂ is the thickness of the insulating and planarizing layer, l₁ is a thickness of the piezoelectric material layer, ε₁ is the dielectric constant of the piezoelectric material layer, and ε₂ is the dielectric constant of the insulating and planarizing layer.

4. The tactile-feedback base board according to claim 1, wherein the insulating and planarizing layer comprises a first insulating and planarizing layer and a second insulating and planarizing layer, the first insulating and planarizing layer is disposed between the first electrode and the piezoelectric material layer, the second insulating and planarizing layer is disposed between the second electrode and the piezoelectric material layer, and a thickness of the first insulating and planarizing layer and a thickness of the second insulating and planarizing layer satisfy a following relation:
$$10 nm \leq {l}_{0} \leq [ ( \frac{{ε}_{2} - {ε}_{1}}{2 {ε}_{2} - {ε}_{1}} ) {l}_{1} - {l}_{1} ] nm ;$$
wherein l₀ is a sum of the thickness of the first insulating and planarizing layer and the thickness of the second insulating and planarizing layer, l₁ is a thickness of the piezoelectric material layer, ε₁ is the dielectric constant of the piezoelectric material layer, and ε₂ is a dielectric constant of the first insulating and planarizing layer.

5. The tactile-feedback base board according to claim 1, wherein a quantity of the piezoelectric element is more than one, and a plurality of piezoelectric elements are arranged in an array at one side of the substrate;
the first electrodes of all of the piezoelectric elements are planar electrodes of an integral structure, the second electrodes of the piezoelectric elements located in a same column are electrically connected to each other by electrically conductive connecting parts, the second electrodes of the piezoelectric elements located in different columns are insulated from each other, and the piezoelectric material layers of the piezoelectric elements located in the same column are connected to each other by piezoelectric connecting parts; and
the insulating and planarizing layers and the piezoelectric material layers have a same shape and equal sizes.

6. The tactile-feedback base board according to claim 5, wherein edges of the second electrodes are retracted relative to edges of the piezoelectric material layers.

7. The tactile-feedback base board according to claim 6, wherein a retraction amount of the edges of the second electrodes relative to the edges of the piezoelectric material layers is greater than or equal to 50 micrometers, and less than or equal to 100 micrometers.

8. The tactile-feedback base board according to claim 5, wherein sizes of the piezoelectric elements located in the same column are equal, and the piezoelectric elements located in a same row are arranged alternately based on a first size and a second size, wherein the first size is greater than the second size.

9. The tactile-feedback base board according to claim 1, wherein the tactile-feedback base board further comprises:
a bonding electrode disposed in a same layer as the first electrode, wherein the bonding electrode is disposed closely to an edge of the substrate, the bonding electrode is for connecting a driving-voltage inputting terminal, and a voltage signal inputted by the driving-voltage inputting terminal is an alternating voltage signal;
an insulating layer disposed at one side of the second electrode away from the substrate; and
a trace layer disposed at one side of the insulating layer away from the substrate, wherein the trace layer comprises a trace, one end of the trace is connected to the second electrode by a first via hole disposed in the insulating layer, and the other end of the trace is connected to the bonding electrode by a second via hole disposed in the insulating layer.

10. The tactile-feedback base board according to claim 9, wherein the tactile-feedback base board further comprises a lead-wire electrode disposed in the same layer as the first electrode, the lead-wire electrode is connected to the first electrode, the lead-wire electrode is for connecting a ground-voltage inputting terminal, and a voltage signal inputted by the ground-voltage inputting terminal is a grounded voltage signal.

11. The tactile-feedback base board according to claim 9, wherein a material of the insulating layer is SiO₂ or a photoresist.

12. The tactile-feedback base board according to claim 9, wherein a material of the first electrode and a material of the second electrode are a transparent electrically conductive material, and a material of the trace layer is Ti/Ni/Au or Ti/Al/Ti.

13. The tactile-feedback base board according to claim 1, wherein a thickness of the piezoelectric material layer is 500 nm-2000 nm.

14. The tactile-feedback base board according to claim 1, wherein the piezoelectric material layer comprises at least one of lead zirconate titanate, aluminium nitride, zinc oxide, barium titanate, lead titanate, potassium niobate, lithium niobate, lithium tantalate and gallium lanthanum silicate.

15. A tactile-feedback device, wherein the tactile-feedback device comprises the tactile-feedback base board according to claim 1.

16. The tactile-feedback device according to claim 15, wherein a material of the insulating and planarizing layer comprises at least one of HfO₂, Al₂O₃, AlN or PbZrO₃.

17. The tactile-feedback device according to claim 15, wherein the insulating and planarizing layer is disposed between the first electrode and the piezoelectric material layer or between the second electrode and the piezoelectric material layer, and a thickness of the insulating and planarizing layer satisfies a following relation:
$$10 nm \leq {l}_{2} \leq [ ( \frac{{ε}_{2} - {ε}_{1}}{2 {ε}_{2} - {ε}_{1}} ) {l}_{1} - {l}_{1} ] nm ;$$
wherein l₂ is the thickness of the insulating and planarizing layer, l₁ is a thickness of the piezoelectric material layer, ε₁ is the dielectric constant of the piezoelectric material layer, and ε₂ is the dielectric constant of the insulating and planarizing layer.

18. The tactile-feedback device according to claim 15, wherein the insulating and planarizing layer comprises a first insulating and planarizing layer and a second insulating and planarizing layer, the first insulating and planarizing layer is disposed between the first electrode and the piezoelectric material layer, the second insulating and planarizing layer is disposed between the second electrode and the piezoelectric material layer, and a thickness of the first insulating and planarizing layer and a thickness of the second insulating and planarizing layer satisfy a following relation:
$$10 nm \leq {l}_{0} \leq [ ( \frac{{ε}_{2} - {ε}_{1}}{2 {ε}_{2} - {ε}_{1}} ) {l}_{1} - {l}_{1} ] nm ;$$
wherein l₀ is a sum of the thickness of the first insulating and planarizing layer and the thickness of the second insulating and planarizing layer, l₁ is a thickness of the piezoelectric material layer, ε₁ is the dielectric constant of the piezoelectric material layer, and ε₂ is a dielectric constant of the first insulating and planarizing layer.

19. The tactile-feedback device according to claim 15, wherein a quantity of the piezoelectric element is more than one, and a plurality of piezoelectric elements are arranged in an array at one side of the substrate;
the first electrodes of all of the piezoelectric elements are planar electrodes of an integral structure, the second electrodes of the piezoelectric elements located in a same column are electrically connected to each other by electrically conductive connecting parts, the second electrodes of the piezoelectric elements located in different columns are insulated from each other, and the piezoelectric material layers of the piezoelectric elements located in the same column are connected to each other by piezoelectric connecting parts; and
the insulating and planarizing layers and the piezoelectric material layers have a same shape and equal sizes.

20. The tactile-feedback device according to claim 19, wherein edges of the second electrodes are retracted relative to edges of the piezoelectric material layers.
